(19) United States
(12) Patent Application Publication
(10) Pub. No.: US 2008/0112126 A1
(43) Pub. Date: May 15, 2008

(54) Releasing device for releasing hard disk drive

(75) Inventor: Mei-Man Hsu, Kaohsiung City (TW)

Correspondence Address: HAVERSTOCK & OWENS LLP, 162 N WOLFE ROAD, SUNNYVALE, CA, 94086, US

(73) Assignee: Delta Electronics, Inc.

(21) Appl. No.: 11/818,184

(22) Filed: Jun. 12, 2007

(30) Foreign Application Priority Data
Nov. 15, 2006 (TW) 95142329

(51) Int. Cl. H05K 13/04

(52) U.S. Cl. 361/685

(57) ABSTRACT

A releasing device for releasing the hard disk drive is provided. The releasing device includes a housing, a first releasing component, a second releasing component and a third releasing component. The housing is used to contain the hard disk drive therein. The first releasing component is mounted on the housing and having a first front end and a first back end. The second releasing component has a second front end, a second back end and a fixed point fixed to the housing, wherein the second front end is connected to the first back end of the first releasing component, the fixed point mounted between the second front end and the second back end for serving as a pivoting center, and the second front end revolves around the pivoting center while the first releasing component is moved. The third releasing component has a third front end and a third back end, wherein the third front end is connected to the second back end of the second releasing component, and the third back end of the third releasing component pushes the hard disk drive for releasing the hard disk drive from the housing while the second releasing component is pivoted.

### FIELD OF THE INVENTION

The present invention relates to a releasing device for releasing a hard disk drive, and more particularly to a releasing device configured in a vehicle for releasing a hard disk drive therein.

### BACKGROUND OF THE INVENTION

As the modern people pay more attention to their life quality, they spend more time on the holiday tour. In other words, people will take more time on their automobiles during their journey. Hence, the necessities for the entertainment equipments disposed on the automobiles, including video devices, digital camera, DVD players, video games and GPS devices, might highly increase.

In the current commercial automobile market, the multi-media equipments become more popular and thus the necessity for mounting the hard disk drive (HDD) module to support the mentioned device becomes imperative. However, if such expensive HDD module equipments directly mounted on the automobiles, drivers might be worry about the piracy. Further, the application of the HDD module might be limited to only support those entertainment equipments on the automobiles.

From the above description, it is known that how to provide a releasing device for releasing the HDD module has become a major problem waited to be solved. In order to overcome the drawbacks in the prior art, an improved input component is provided. The particular design in the present invention not only solves the problems described above, but also is easy to be implemented. Thus, the invention has the utility for the industry.

### SUMMARY OF THE INVENTION

In accordance with one aspect of the present invention, a releasing device for releasing a hard disk drive is provided. The releasing device comprises a housing, a first releasing component, a control component, a second releasing component and a third releasing component. The housing is used to contain the hard disk drive therein. The first releasing component is mounted on the housing and has a first front end and a first back end. The control component is connected to the first front end of the first releasing component for controlling whether an external force is to be applied to the first releasing component. The second releasing component has a second front end, a second back end and a fixed point fixed to the housing, wherein the second front end is connected to the first back end of the first releasing component, the fixed point is mounted between the second front end and the second back end for serving as a pivoting center, and the second front end revolves around the pivoting center while the first releasing component is moved. The third releasing component has a third front end and a third back end, wherein the third front end is connected to the second back end of the second releasing component, and the third back end of the third releasing component pushes the hard disk drive for releasing the hard disk drive from the housing while the second releasing component is pivoted.

Preferably, the housing has a lateral side and the first releasing component is mounted on the lateral side of the housing.

Preferably, the control component comprises a pivotable portion, the pivotable portion in a first position enables the application of the external force to the first releasing component and the pivotable portion in a second position disables the application of the external force to the first releasing component.

Preferably, the housing has an opening on a side thereof.

Preferably, the third back end of the third releasing component comprises a protruding portion passing through the opening.

Preferably, the first releasing component is a pushing bar.

Preferably, the control component is a pressing button.

Preferably, the second releasing component is a revolving bar.

Preferably, the third releasing component is a pushing plate.

Preferably, the releasing device for releasing the hard disk drive is configured in a vehicle.

In accordance with another aspect of the present invention, a releasing device for releasing the hard disk drive is provided. The releasing device comprises a housing, a first releasing component, a second releasing component and a third releasing component. The housing is used to contain the hard disk drive therein. The first releasing component is mounted on the housing. The second releasing component has a first end, a second end and a fixed point, wherein the first end is connected to the first releasing component, and the second releasing component moves around the fixed point in response to a movement of the first releasing component. The third releasing component has a third end connected to the second end of the second releasing component, wherein the third releasing component pushes the hard disk drive for releasing the hard disk drive from the housing while the second releasing component is moved.

Preferably, the third releasing component further comprises a fourth end to push the hard disk drive while the second released component is moved for releasing the hard disk drive from the housing.

Preferably, the housing has a lateral side and the first releasing component is mounted on the lateral side of the housing.

Preferably, the housing has an opening on a side thereof.

Preferably, the fourth end of the third releasing component comprises a protruding portion passing through the opening.

Preferably, the first releasing component is a pushing bar.

Preferably, the second releasing component is a revolving bar.

Preferably, the third releasing component is a pushing plate.

Preferably, the hard disk drive is configured in a vehicle.

The foregoing and other features and advantages of the present invention will be more clearly understood through the following descriptions with reference to the drawings, wherein:

### BRIEF DESCRIPTION OF THE DRAWINGS

FIG. 1 is a structural diagram of the respective components of the releasing device before they are packaged according to a first embodiment of the present invention;

FIG. 2(a) is a schematic diagram of the releasing device containing a hard disk drive therein after the components in FIG. 1 are packaged;

FIG. 2(b) is another schematic diagram of the releasing device after the hard disk drive in FIG. 2(a) is released from the housing;

FIG. 3 is a structural diagram of the respondent components of the releasing device before they are packaged according to a second embodiment of the present invention; and

FIG. 4(a) is a schematic diagram of the releasing device containing a hard disk drive therein after the components in FIG. 3 are packaged;

FIG. 4(b) is another schematic diagram of the releasing device after the hard disk drive in FIG. 4(a) is released from the housing;

FIG. 5 is an appearance diagram of the releasing device for releasing the hard disk drive according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

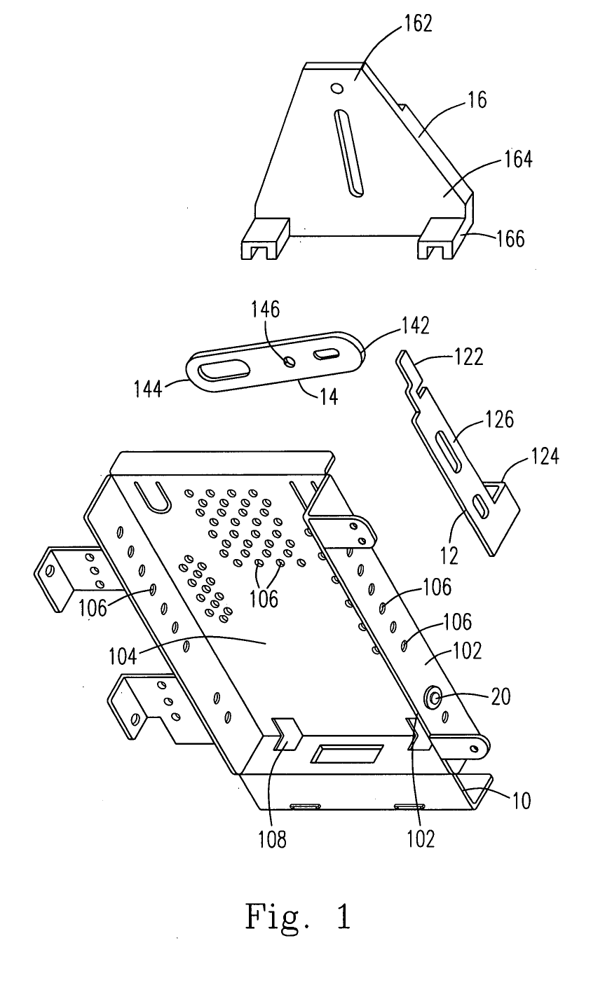

Please refer to FIG. 1, which depicts a structural diagram of the respective components of the releasing device before they are packaged according to a first embodiment of the present invention. The present releasing device includes a housing 10, a first releasing component 12, a second releasing component 14 and a third releasing component 16. A portable hard disk drive (not shown in FIG. 1) inserts into the housing 10 capable of supporting and immobilizing the hard disk drive therein. The first releasing component 12 is mounted onto the housing 10 and has a first front end 122 and a first back end 124. The second releasing component 14 has a second front end 142, a second back end 144 and a fixed point 146 fixed to the housing 10. The second front end 142 of the second releasing component 14 is connected to the first back end 124 of the first releasing component 12 and the second releasing component 14 revolves around the fixed point 146 through the connection to the first releasing component 12. The third releasing component 16 has a third front end 162 and a third back end 164. The third front end 162 of the third releasing component 16 is connected to the second back end 144 of the second releasing component 14 and the third back end 164 of the third releasing component 16 pushes the hard disk drive contained in the housing 10 through the connection to the second releasing component 14.

Please refer to FIG. 1 again, the housing 10 has a lateral side 102 and a bottom side 104 where there are a plurality of holes 106 mounted thereon. The first releasing component 12 has a hollow portion 126 that is fixed on one of the plurality of holes 106 of the lateral side 102 of the housing 10 with more than one buckle 20; thus the hollow portion 126 of the first releasing component 12 is capable of sliding along the lateral side 102 of the housing 10 by means of the buckle 20 fixed to the hollow portion 126. The first back end 124 of the first releasing component 12 extends to the bottom side 104 of the housing 10 and is perpendicular to the lateral side 102. The second front end 142 of the second releasing component 14 is connected to the first back end 124 of the first releasing component 12. The second releasing component 14 has a fixed point 146 that mounted between the second front end 142 and the second back end 144. The fixed point 146 is fixed to the bottom side 104 of the housing 10 with the buckle 20 and serves as a pivoting center so that the first releasing component 12 revolves therearound. The third front end 162 of the third releasing component 16 is connected to the second back end 144 of the second releasing component 14. The housing 10 further comprises two respective openings 108 and the third back end 164 of third releasing component 16 comprises two respective protruding portions 166 passing through the openings 108.

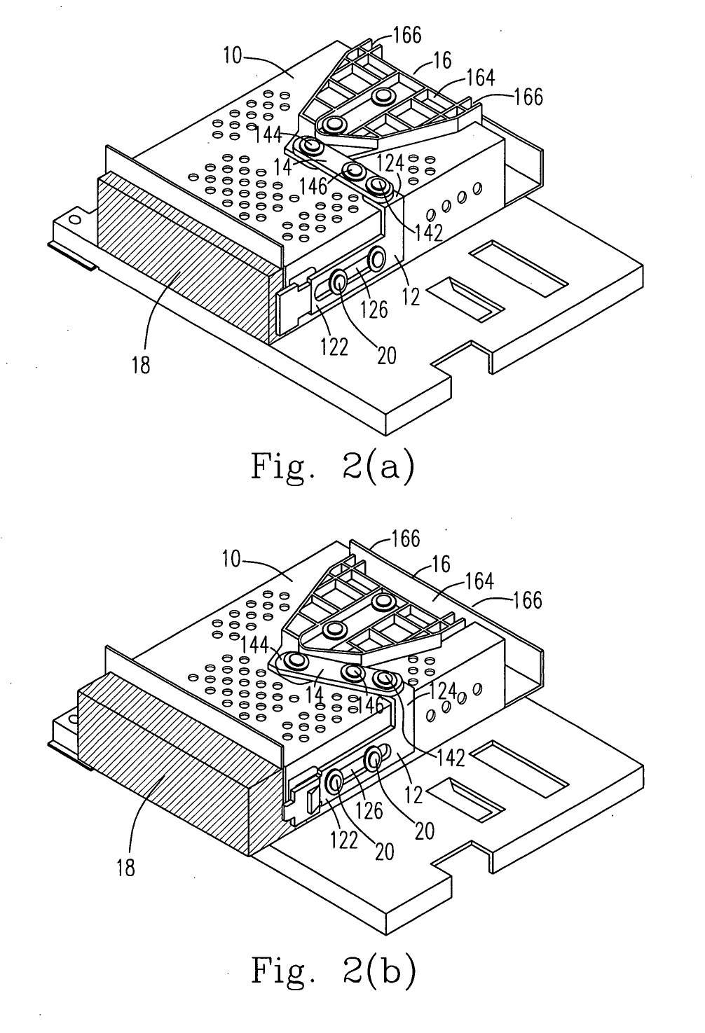

Please refer to FIG. 2(a) and 2(b), which depict structural diagrams after the respective components of the releasing device in FIG. 1 are packaged according to the first embodiment of the present invention. FIG. 2(a) shows a schematic diagram of the releasing device containing a hard disk drive 18 therein after the components in FIG. 1 are packaged. The first releasing component 12 mounted on the housing 10 utilizes the number of the buckle 20 to control the distance that the first releasing component 12 slides on the lateral side 102 of the housing 10. While the first front end 122 of the first releasing component 12 receives an external force, the first releasing component 12 slides towards the opposite direction of the received external force. Then, the second front end 142 of the second releasing component 14 revolves around the fixed point 146. Correspondingly, the second back end 144 also revolves around the fixed point 146 in the opposite direction to the second front end 142. The movement of the second back end 144 drives the third front end 162 of the third releasing component 16 and then the protruding portions 166 of the third back end 164 moves to push out the hard disk drive 18 from the housing 10. FIG. 2(b) depicts another schematic diagram of the releasing device after the hard disk drive in FIG. 2(a) is released from the housing 10. Accordingly, the released hard disk drive 18 could be easily accessed.

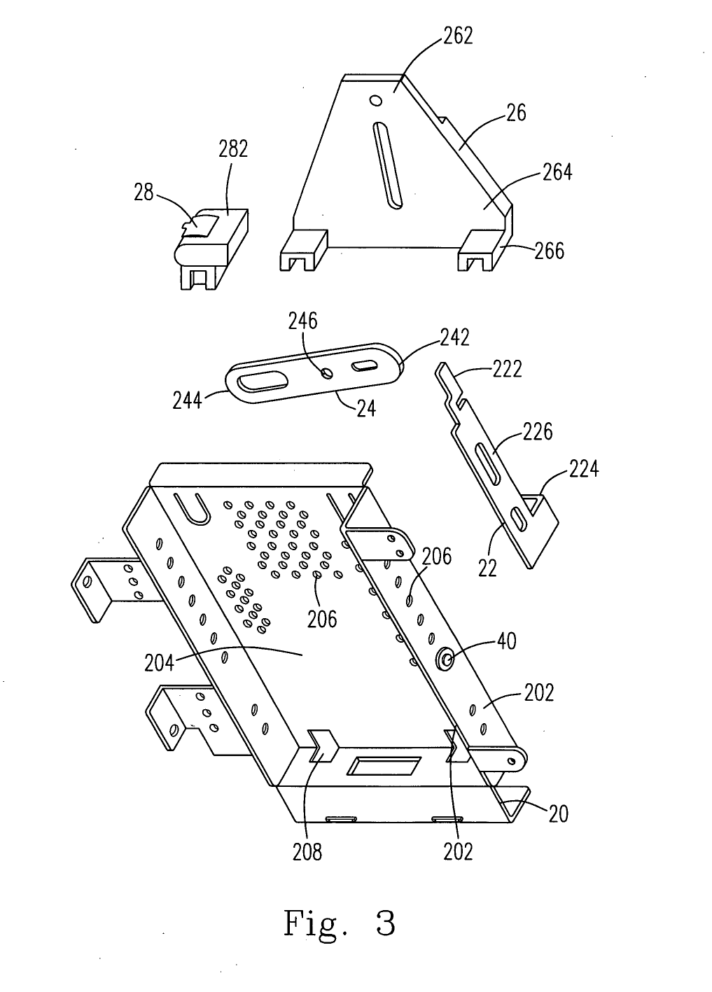

Please refer to FIG. 3, which depicts a structural diagram of the respective components of the releasing device before they are packaged according to a second embodiment of the present invention. The present releasing device for releasing the hard disk drive comprises a housing 20, a first releasing component 22, a second releasing component 24, a third releasing component 26 and a control component 28. The housing 20 is used to contain a hard disk drive (not shown in FIG. 3) and capable of supporting and immobilizing the hard disk drive therein. The first releasing component 22 is mounted on the housing 20 and has a first front end 222 and a first back end 224. The control component 28, such as a pressing button, is connected to the first front end 222 of the first releasing component 22 to control whether an external force is applied to the first releasing component 22. The second releasing component 24 has a second front end 242, a second back end 244 and a fixed point 246, wherein the second front end 242 is connected to the first back end 224 of the first releasing component 22 and the second releasing component 24 revolves around the fixed point 246 that serves as a pivoting center, while the first releasing component 22 is moved. The third releasing component 26 has a third front end 262 and a third back end 264, wherein the third front end 262 is connected to the second back end 244 of the second releasing component 24. The third back end 264 of the third releasing component 26 pushes out the hard disk drive from the housing 20 while the second releasing component 24 is pivoted.

Please refer to FIG. 3 again. The housing 20 has a lateral side 202 and a bottom side 204 where there are a plurality of holes 206 disposed thereon. The first releasing component 22 has a hollow portion 226 and the first releasing component 22 is fixed on the lateral side 202 of the housing 20 with more than one buckle 40 immobilized to the hollow portion 226. Accordingly, the first releasing component 22 is capable of sliding along the lateral side 202 of the housing 20. The first back end 224 of the first releasing component 22 extends to the bottom side 204 and perpendicular to the lateral side 202 of the housing 20. The control component 28 comprises a pivoting portion 282 to prevent the hard disk drive from being pushing out from the housing 20 due to the unsuitable external force. Users could revolve the pivoting portion 282 about 90 degrees and then apply an external force to the control component 28. Subsequently, the first releasing component 22 is moved along the lateral side 202 due to the passing external force from the control component 28. The second front end 242 of the second releasing component 24 is connected to the first back end 224 of the first releasing component 22. The second releasing component 24 is fixed on the bottom side 204 of the housing 20 with a buckle 40 immobilized to the fixed point 246 so that the second releasing component 24 revolves around the fixed point 246. The third front end 262 of the third releasing component 26 is connected to the second back end 244 of the second releasing component 24. The housing 20 further comprises two respective openings 208 and the third back end 264 of the third releasing component 26 comprises two respective protruding portions 266 passing through the opening 208.

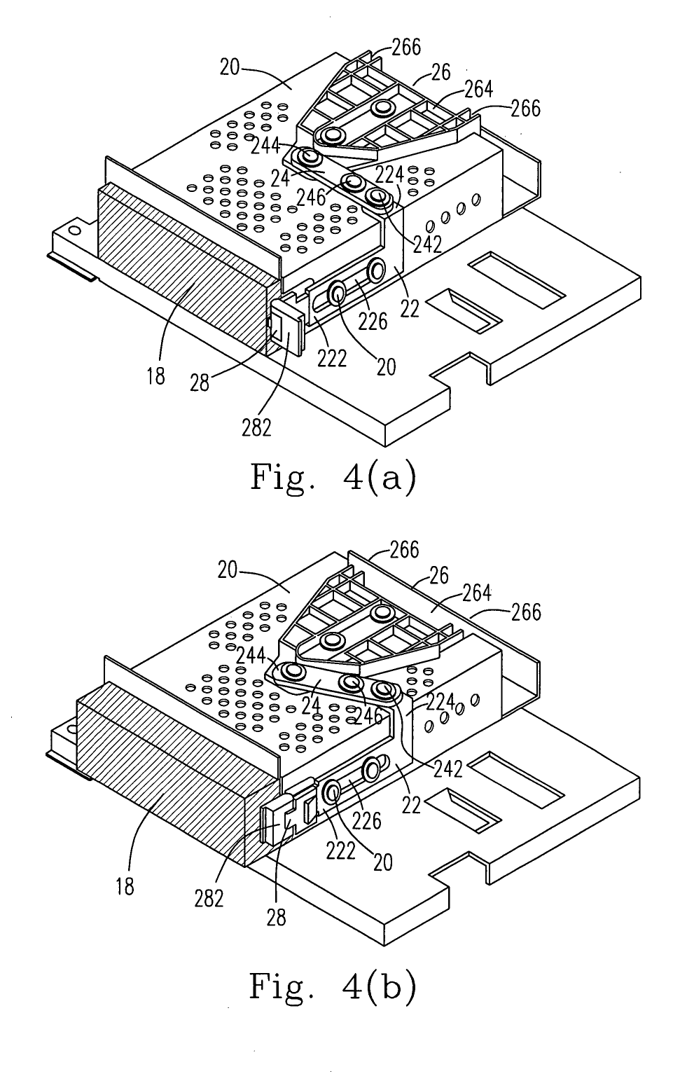

Please refer to FIG. 4(a) and 4(b), which depict the structural diagrams of the respective components of the releasing device in FIG. 3 after they are packaged according to the second embodiment of the present invention. FIG. 4(a) shows a schematic diagram of the releasing device containing a hard disk drive 18 therein after the components in FIG. 3 are packaged. While an external force is applied to the control component 28, the external force is passing through the first releasing component 22 connected thereto and thus the first releasing component 22 slides along the opposite direction of the applied external force. Similarly, the second releasing component 24 receives the force passing from the first releasing component 22 so that the second front end 242 revolves around the pivoting center and the second back end 244 also revolves around the fixed point 246 in the opposite direction to the second front end 242. The third front end 262 connected to the second back end 244 is also driven so that the protruding portions 266 of the third back end 264 move towards the direction of the hard disk drive 18. Therefore, the hard disk drive 18 contained within the housing 20 is pushed out by the protruding portions 266 of the third releasing component 26. Please refer to FIG. 4(b), which depicts another schematic diagram of the releasing device after the hard disk drive in FIG. 4(a) is released from the housing 20. Therefore, the released hard disk drive 18 could be easily accessed.

As the mentioned, the present first releasing component could be a pushing bar or an arbitrary component capable of receiving an external force and is not limited to examples of the mentioned embodiments. Any kinds of structures comprising a first front end, a first back end and capable of receiving an external force and driving the elements connected thereto are not escaped from the definition of the first releasing component of the present invention.

The present second releasing component could be a revolving bar or a revolving element and is not limited to the examples of the mentioned embodiments. Any kinds of structures comprising a second front end, a second back end and a fixed point and capable of revolving around the fixed point to drive the elements connected thereto are not escaped from the definition of the second releasing component of the present invention.

The present third releasing component could be a pushing plate or a pushing element and is not limited to the examples of the mentioned embodiments. Any kinds of structures comprising a third front end and a third back end with a protruding portion and capable of releasing the hard disk drive therein are not escaped from the definition of the third releasing component of the present invention.

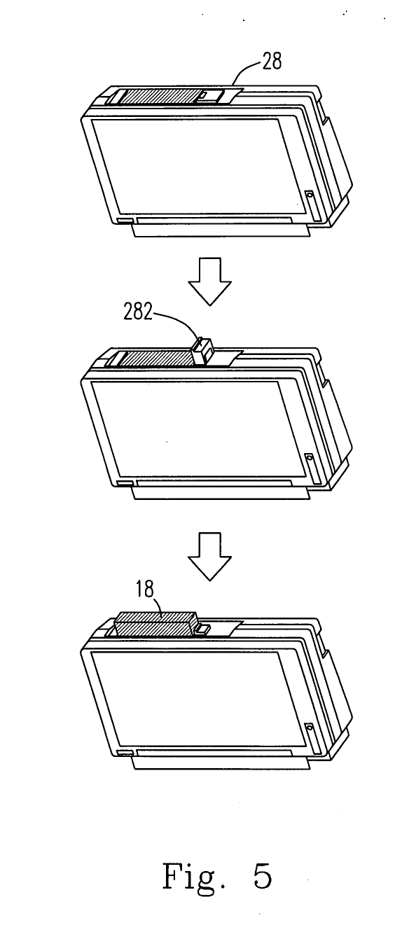

Please refer to FIG. 5, which depicts an appearance diagram of the releasing device for releasing the hard disk drive according to the present invention. At first, rotate the pivoting portion 282 about 90 degrees, then press the control component 28 and the hard disk drive 18 is released.

Through the assistance of the mentioned releasing device, users only press the control component so that the first releasing component moves to drive the rotation of the second releasing component, followed by driving the third releasing component to push out the hard disk drive from the housing. In such way, the portable hard disk drive for supporting the multi-media equipments in the automobiles could easily take to the home or office for a further use though the present releasing device for releasing the hard disk drive.

Furthermore, the present releasing device could be applied to any kinds of vehicles, such as a bus, an automobile, a train, a MRT and an airplane. The position that the releasing device mounted on the vehicle could be within the control table, the headrest and the seat back and under the seat.

In conclusion, the present invention provides a releasing device mounted on the vehicle for releasing the hard disk drive. Users could easily take the hard disk drive from the vehicle and bring to anywhere they want to use. Moreover, the present releasing device could reduce the users' worries that the expensive devices mounted on the vehicle might be stolen. Accordingly, the present invention can effectively solve the problems and drawbacks in the prior art, and thus it fits the demand of the industry and is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A releasing device for releasing a hard disk drive, comprising:
a housing for containing the hard disk drive therein;
a first releasing component mounted on the housing and having a first front end and a first back end;
a control component connected to the first front end of the first releasing component for controlling whether an external force is to be applied to the first releasing component;
a second releasing component having a second front end, a second back end and a fixed point fixed to the housing, wherein the second front end is connected to the first back end of the first releasing component, the fixed point mounted between the second front end and the second back end for serving as a pivoting center, and the second front end revolves around the pivoting center while the first releasing component is moved; and
a third releasing component having a third front end and a third back end, wherein the third front end is connected to the second back end of the second releasing component, and the third back end of the third releasing component pushes the hard disk drive for releasing the hard disk drive from the housing while the second releasing component is pivoted.

2. A releasing device as claimed in claim 1, wherein the housing has a lateral side and the first releasing component is mounted on the lateral side of the housing.

3. A releasing device as claimed in claim 1, wherein the control component comprises a pivotable portion, the pivotable portion in a first position enables the application of the external force to the first releasing component and the pivotable portion in a second position disables the application of the external force to the first releasing component.

4. A releasing device as claimed in claim 1, wherein the housing has an opening on a side thereof.

5. A releasing device as claimed in claim 4, wherein the third back end of the third releasing component comprises a protruding portion passing through the opening.

6. A releasing device as claimed in claim 1, wherein the first releasing component is a pushing bar.

7. A releasing device as claimed in claim 1, wherein the control component is a pressing button.

8. A releasing device as claimed in claim 1, wherein the second releasing component is a revolving bar.

9. A releasing device as claimed in claim 1, wherein the third releasing component is a pushing plate.

10. A releasing device as claimed in claim 1, being configured in a vehicle.

11. A releasing device for releasing a hard disk drive, comprising:
a housing for containing the hard disk drive therein;
a first releasing component mounted on the housing;
a second releasing component having a first end, a second end and a fixed point, wherein the first end is connected to the first releasing component, and the second releasing component moves around the fixed point in response to a movement of the first releasing component; and
a third releasing component having a third end connected to the second end of the second releasing component, wherein the third releasing component pushes the hard disk drive for releasing the hard disk drive from the housing while the second releasing component is moved.

12. A releasing device as claimed in claim 11, wherein the third releasing component further comprises a fourth end to push the hard disk drive while the second released component is moved for releasing the hard disk drive from the housing.

13. A releasing device as claimed in claim 11, wherein the housing has a lateral side and the first releasing component is mounted on the lateral side of the housing.

14. A releasing device as claimed in claim 11, wherein the housing has an opening on a side thereof.

15. A releasing device as claimed in claim 14, wherein the fourth end of the third releasing component comprises a protruding portion passing through the opening.

16. A releasing device as claimed in claim 11, wherein the first releasing component is a pushing bar.

17. A releasing device as claimed in claim 11, wherein the second releasing component is a revolving bar.

18. A releasing device as claimed in claim 11, wherein the third releasing component is a pushing plate.

19. A releasing device as claimed in claim 11, being configured in a vehicle.
